(19) United States
(12) Patent Application Publication
(10) Pub. No.: US 2022/0181124 A1
(43) Pub. Date: Jun. 9, 2022

(54) EROSION RESISTANT METAL FLUORIDE COATINGS, METHODS OF PREPARATION AND METHODS OF USE THEREOF

(71) Applicant: APPLIED MATERIALS, INC., Santa Clara, CA (US)

(72) Inventors: Ren-Guan Duan, Fremont, CA (US); Christopher Laurent Beaudry, San Jose, CA (US); Glen T. Mori, Gilroy, CA (US)

(21) Appl. No.: 17/110,596

(22) Filed: Dec. 3, 2020

(51) Int. Cl. H01J 37/32

(52) U.S. Cl. CPC H01J 37/32504

(57) ABSTRACT

Embodiments of the disclosure relate to articles, coated chamber components, methods of coating chamber components and systems with a metal fluoride coating that includes at least one metal fluoride having a formula of M1ₓF_{w}, M1ₓM2_{y}F_{w} or M1ₓM2_{y}M3_{z}F_{w}, where at least one of M1, M2, or M3 is nickel. The metal fluoride coating can be formed directly on a substrate or on a coating of a substrate.

### TECHNICAL FIELD

Embodiments of the present disclosure relate to erosion resistant metal fluoride coated articles, coated chamber components and methods of forming and using such coated articles and chamber components.

### BACKGROUND

Various semiconductor manufacturing processes use high temperatures, high energy plasma (such as remote and direct fluorine plasma such as NF₃, CF₄, and the like), a mixture of corrosive gases, corrosive cleaning chemistries (e.g., hydrofluoric acid) and combinations thereof. These extreme conditions may result in a reaction between materials of components within the chamber and the plasma or corrosive gases to form metal fluorides, particles, other trace metal contaminates and high vapor pressure gases (e.g., AlFₓ). Such gases may readily sublime and deposit on other components within the chamber. During a subsequent process step, the deposited material may release from the other components as particles and fall onto the wafer causing defects. Additional issues caused by such reactions include deposition rate drift, etch rate drift, compromised film uniformity, and compromised etch uniformity. It is beneficial to reduce these defects with a stable, non-reactive coating on the reactive materials to limit the sublimation and/or formation of particles and metal contaminants on components within the chamber.

### SUMMARY

Disclosed herein, according to embodiments, is a chamber component for a processing chamber, comprising: a substrate; and a metal fluoride coating on the substrate, the metal fluoride coating comprising at least one of: a formula M1ₓF_{w}, wherein x has a value of 1 and w has a value from 1 to 3; a formula M1ₓM2_{y}F_{w}, wherein x has a value from 0.1 to 1, y has a value from 0.1 to 1, and w has a value from 1 to 3; or a formula M1ₓM2_{y}M3_{z}F_{w}, wherein x has a value from 0.1 to 1, y has a value from 0.1 to 1, z has a value from 0.1 to 1 and w has a value from 1 to 3, and wherein at least one of M1, M2, or M3 comprises nickel.

In further embodiments, disclosed herein is a method for reducing particles during processing in a processing chamber, comprising: contacting a substrate with fluorine to form a metal fluoride coating, wherein the metal fluoride coating comprises at least one of: a formula wherein x has a value of 1 and w has a value from 1 to 3; a formula M1ₓM2_{y}F_{w}, wherein x has a value from 0.1 to 1, y has a value from 0.1 to 1, and w has a value from 1 to 3; or a formula M1ₓM2_{y}M3_{z}F_{w}, wherein x has a value from 0.1 to 1, y has a value from 0.1 to 1, z has a value from 0.1 to 1 and w has a value from 1 to 3, and wherein at least one of M1, M2, or M3 comprises nickel.

In yet further embodiments, disclosed herein is a processing chamber, comprising: a chamber component, comprising: a substrate; and a metal fluoride coating on a surface of the substrate, the metal fluoride coating comprising at least one of: a formula M1ₓF_{w}, wherein x has a value of 1 and w has a value from 1 to 3; a formula M1ₓM2_{y}F_{w}, wherein x has a value from 0.1 to 1, y has a value from 0.1 to 1, and w has a value from 1 to 3; or a formula M1ₓM2_{y}M3_{z}F_{w}, wherein x has a value from 0.1 to 1, y has a value from 0.1 to 1, z has a value from 0.1 to 1 and w has a value from 1 to 3, and wherein at least one of M1, M2, or M3 comprises nickel.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a cross sectional view of a processing chamber.

FIG. 2A depicts a cross-sectional view of a coated chamber component according to an embodiment.

FIG. 2B depicts a cross-sectional view of a coated chamber component according to an embodiment.

FIG. 2C depicts a cross-sectional view of a coated chamber component according to an embodiment.

FIG. 3A depicts a method for forming a metal fluoride coating on a bulk metal substrate according to an embodiment.

FIG. 3B depicts a method for forming a metal fluoride coating on a coated metal-containing substrate according to an embodiment.

FIG. 3C depicts a method for forming a metal fluoride coating on a coated metal-containing substrate component according to an embodiment.

FIG. 4A depicts a TEM cross-section image, at 50 nm scale, of a metal fluoride coating formed by a molecular fluorine reaction on an electroless metal plated coating.

FIG. 4B depicts a TEM cross-section image, at 100 nm scale, of a metal fluoride coating formed by a radical fluorine reaction on an electroless metal plated coating.

### DETAILED DESCRIPTION

Embodiments disclosed herein describe coated articles, coated chamber components, methods of coating articles and chamber components, methods of reducing or eliminating particles from semiconductor processing chambers, methods of using coated articles and chamber components and processing chambers containing coated chamber components. To reduce reactions between component materials and reactive chemicals and/or plasmas, which form metal fluorides, particles, other trace metal contaminates and/or high vapor pressure gases, a metal fluoride coating (e.g., nickel fluoride) may be formed on a surface of the component surface by contacting the component with fluorine gas at a temperature of, for example, about 100° C. to about 500° C. for a period of about 1 hour to about 72 hours (i.e., in a controlled process to form a stable protective coating). The metal fluoride coating may form a conformal coating on the surface of the component.

In embodiments, the substrate may include nickel, which is useful in high temperature applications (e.g., at temperatures higher than those required for sputtering resistance). Nickel has mechanical properties, that is, physical properties that a material exhibits upon the application of forces (e.g., modulus of elasticity, tensile strength, elongation, hardness, fatigue limit, etc.), that exceed those of other metals (e.g., aluminum, other metals and alloys used in low temperature applications). Nickel may be used in applications with temperatures up to about 800° C. for bulk nickel substrates and up to about 1,000° C. if the substrate is ceramic.

In embodiments, a coated chamber component includes a substrate having a metal fluoride coating on a surface of the substrate. In embodiments, the substrate may be formed of a bulk metal material, a bulk ceramic material, an aluminum alloy, aluminum nitride (AlN), alumina (Al₂O₃), stainless steel, nickel, nickel-chromium alloys, austenitic nickel-chromium-based superalloys (e.g., Inconel®), pure nickel, carpenter nickel (Ni 200/201), quartz, iron, cobalt, titanium, magnesium, copper, zinc, chromium or other metals and/or combinations thereof. In embodiments, the substrate may be coated with an electroless metal plated coating, an electrolytic plated metal fluoride coating, and/or combinations thereof. In some embodiments, the substrate is formed of bulk nickel (Ni) and/or may contain an electroless nickel plated (ENP) coating or an electrolytic plated Ni coating on a surface thereof.

Exemplary substrates include, without limitation, semiconductor chamber components positioned in an upper portion of a processing chamber (e.g., showerhead, faceplate, liner, electrostatic chuck, edge ring, blocker plate) as well as in a lower portion of a processing chamber (e.g., sleeve, lower liner, bellows, gas box). Certain semiconductor process chamber components that may be have a metal fluoride coating described herein may have portions with a high aspect ratio (e.g., a length to diameter or length to width ratio of about 1000:1, about 500:1, about 400:1, about 300:1, 200:1, 100:1, and so on), and the surface of the portion with the high aspect ratio may be coated with metal fluoride coatings described herein. In embodiments, the semiconductor process chamber component may be suitable for high temperature applications.

The metal fluoride coating described herein may include at least one metal fluoride having a formula M1ₓF_{w}, M1ₓM2_{y}F_{w}, and M1ₓM2_{y}M3_{z}F_{w}, wherein: a) when the metal fluoride formula is M1ₓF_{w}, x is 1, and w ranges from 1 to 3, b) when the metal fluoride formula is M1ₓM2_{y}F_{w}, x ranges from 0.1 to 1, y ranges from 0.1 to 1, and w ranges from 1-3, and c) when the metal fluoride formula is M1ₓM2_{y}M3_{z}F_{w}, x ranges from 0.1 to 1, y ranges from 0.1 to 1, z ranges from 0.1 to 1, and w ranges from 1 to 3. In embodiments, at least one of M1, M2, or M3 is nickel. M1, M2, and M3 each represent a different metal, such as, without limitations, nickel, magnesium, aluminum, cobalt, chromium and/or yttrium. Without being construed as limiting, nickel containing metal fluorides are believed to be suitable metal fluoride coating candidates because the reaction product of a nickel fluoride converted coating with a fluorine containing plasma is believed to absorb and saturate the coating with fluorine, yet protect the underlying substrate. An exemplary metal fluoride coating as defined above may include NiₓF_{w}. In embodiments, the coating is a converted and conformal nickel fluoride coating that improves chamber performance and has beneficial chemistry, thermal, plasma and radical erosion/corrosion resistance as compared to nickel plated electroless coatings or other metal oxide coatings.

In some embodiments, a substrate may be coated following an electroless deposition process to form an electroless metal plated coating on a surface of the substrate. The electroless metal plated coating may be contacted with fluorine to form the metal fluoride coating. In embodiments, electroless metal plated coating layer may be a nickel-phosphorous coating. The electroless deposition process can form a metal plated coating directly on the surface of the substrate. In some embodiments, the substrate may be coated using an electrolytic metal plating process. For example, the electrolytic plating process may form a layer containing nickel, silver and gold plating. In embodiments, the electrolytic metal plated coating may be applied on an substrate material as described herein including high purity copper or a copper alloy surface including C101 and BeCu25 or other materials. The metal plated coatings described herein may be applied on chamber critical components such as a heater RF strap and faceplate/gas box RF strap.

In some embodiments, a metal fluoride coating on a substrate may be formed by using a thermal molecular fluorine gas (F₂) conversion (Ni+F₂=NiF₂) process. In some embodiments, a metal fluoride coating on a substrate may be formed by using a fluorine radical (F*) conversion (Ni+2F=NiF₂) process. Converted coatings formed by either the molecular fluorine gas process or the fluorine radical process, have an adhesive strength to the surface of the substrate of greater than about 20 mN with a 2 μm diamond stylus or 100 mN with a 10 μm diamond stylus using a Scratch Adehsion Test per ASTM C1624, D7187, G171 or other equivalent standard. The resulting converted coatings are conformal and capable of coating complex features including high aspect ratio features of the substrate (e.g., having an aspect ratio of length to diameter or length to width of about 100:1 to about 1000:1). The thickness of the resulting metal fluoride coating may be about 5 nm to about 5,000 nm, or about 10 nm to about 4,000 nm, or about 25 nm to about 3,000 nm, or about 50 nm to about 2,500 nm, or about 100 nm to about 2,000 nm, or about 250 nm to about 1,000 or any individual thickness or sub-range within these broad ranges. The coating thickness may be a function of reaction time of the fluorine gas or radicals with the surface of the coating. The resulting converted coatings may be crystalline and dense (e.g., having an approximately 0% porosity or zero porosity) and may provide better ion bombardment resistance than amorphous coatings. The metal fluoride coatings described herein provide fluorine plasma and/or radical erosion resistance as well as oxygen, hydrogen and nitrogen plasma resistance with stable properties. Because the metal fluoride coatings as described herein already contain metal fluorides and may be considered pre-saturated with fluorine. When exposed to fluorine, the metal fluoride coating absorbs fluorine like a sponge.

In embodiments, the metal fluoride coating comprises nickel fluoride and is anhydrous. The anhydrous metal fluoride coating may be non-hygroscopic, unless it is mixed with hydrated nickel fluoride. The anhydrous converted nickel fluoride coating may be crystalline and, if exposed to moisture, may retain water only by physical absorption. Notably, passivated NiF₂ at 300° C. is anhydrous, anhydrous NiF₂ is non-hygroscopic unless mixed with hydrated NiF₂, anhydrous NiF₂ forms tetragonal crystals of the rutile type, anhydrous NiF₂ exposed to moisture only take up water by physical absorption, anhydrous NiF₂ is nearly insoluble with a value of 0.02 g/100 mL, and when hydrated NiF₂ (NiF₂.4H₂O) is formed by hydroxide, nitrate or carbonate solution and reacted with HF acid, the hydrate changes to anhydrous NiF₂ at 350° C. in dry HF. NiF₂.4H₂O is a stable hydrate whereas other hydrates NiF₂.2H₂O and NiF₂.3H₂O) are non-stable. Hydrated NiF₂ (NiF₂.4H₂O) dissolves in water in 4.03 g/100 mL saturated solution.

In one example, the substrate initially may include an electroless metal plated coating on a surface of the substrate. The substrate material may be without limitation one or more of a metal, for example, aluminum, stainless steel and/or titanium, a ceramic, for example, alumina, silica and/or aluminum nitride, and/or combinations thereof. The electroless metal plated coating may be contacted with fluorine gas to convert one or more metal in the metal plated coating to a metal fluoride to form a metal fluoride coating. In embodiments, the metal fluoride coating may be a homogenous or substantially homogenous metal fluoride coating in that at least about 90%, at least about 95%, at least about 96%, at least about 97%, at least about 98%, at least about 99%, or at least about 100% of the one or more metal in the electroless metal plated coating may converted to metal fluoride.

The metal fluoride coatings described herein (e.g., which may include at least a Ni component) may have a lower rate of evaporation (lower vapor pressure) compared to common reaction products of substrates with fluorine containing species (e.g., AlFₓ). Additionally, since the metal fluoride coatings are already fluorinated, they are expected to be more fluorine resistant (i.e., form a better barrier to fluorine diffusion) than the underlying substrate or as compared to the same metal in an oxide form. They are also expected to be more fluorine resistant than a native oxide layer of the material of an underlying substrate.

In embodiments, disclosed herein are chamber components for a processing chambers and/or processing chambers containing such chamber components (e.g., semiconductor processing chambers), wherein the chamber components include a substrate and a metal fluoride coating on the substrate. The metal fluoride coating may include at least one of a formula M1ₓF_{w}, wherein x has a value of 1 and w has a value from 1 to 3; a formula M1ₓM2_{y}F_{w}, wherein x has a value from 0.1 to 1, y has a value from 0.1 to 1, and w has a value from 1 to 3; or a formula M1ₓM2_{y}M3_{z}F_{w}, wherein x has a value from 0.1 to 1, y has a value from 0.1 to 1, z has a value from 0.1 to 1 and w has a value from 1 to 3, and at least one of M1, M2, or M3 comprises nickel. In embodiments, M2 and M3 each independently may be without limitation a metal chosen from magnesium, aluminum, cobalt, chromium, yttrium, titanium, silver, gold, iron and/or zinc.

In embodiments, the metal fluoride coating may further include an electroless metal plated coating layer including nickel or an electrolytic metal plated coating layer including nickel. The metal plated coating layer may be deposited directly on the substrate with the metal fluoride coating formed on the surface of the metal plated coating layer. In embodiments, the electroless metal plated coating layer includes a nano-crystalline structure comprising tetragonal nickel phosphide (Ni₃P) and cubic Ni. In some embodiments, the electroless metal plated coating layer or the electrolytic metal plated coating layer may include phosphorus (P) while the metal fluoride coating formed thereon (e.g., by contacting with fluorine) is free of phosphorus. In embodiments, the metal fluoride coating is crystalline. In some embodiments, the metal fluoride coating includes a tetragonal P4₂/mnm crystalline structure.

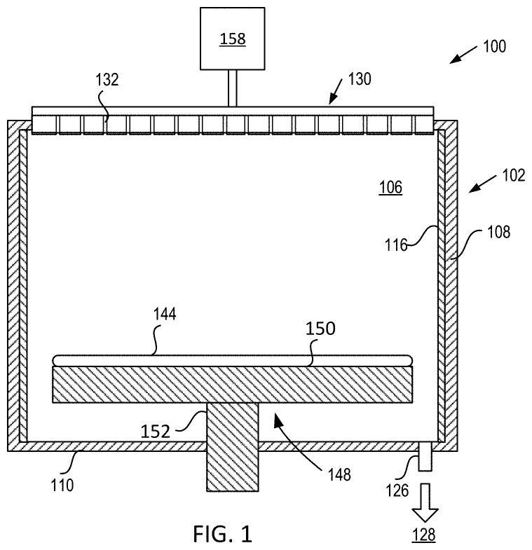

FIG. 1 is a sectional view of a semiconductor processing chamber 100 having one or more chamber components that are coated with a metal fluoride coating in accordance with embodiments. The processing chamber 100 may be used for processes in which a corrosive plasma environment having plasma processing conditions is provided. For example, the processing chamber 100 may be a chamber for a plasma etcher or plasma etch reactor, a plasma cleaner, plasma enhanced CVD, ALD, Etch or EPI reactors and so forth. An example of a chamber component that may include a metal fluoride coating is one that is at risk of exposure to fluorine chemistry and corrosive environment during processing. Such chamber components may be in the upper portion or in the lower portion of the chamber, such as, a heater, electrostatic chuck, faceplate, showerhead, liner, blocker plate, gas panel, edge ring, bellow, and the like. The metal fluoride coating, which is described in greater detail below, may be applied by an electroless metal plated coating that is reacted with fluorine gas.

In one embodiment, the processing chamber 100 includes a chamber body 102 and a showerhead 130 that encloses an interior volume 106. The showerhead 130 may include a showerhead base and a showerhead gas distribution plate. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material such as titanium (Ti). The chamber body 102 generally includes sidewalls 108 and a bottom 110. An outer liner 116 may be disposed adjacent the sidewalls 108 to protect the chamber body 102.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewall 108 of the chamber body 102. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 may include a gas distribution plate (GDP) and may have multiple gas delivery holes 132 throughout the GDP. The showerhead 130 may include the GDP bonded to an aluminum base or an anodized aluminum base. The GDP may be made from Si or SiC, or may be a ceramic such as Y₂O₃, Al₂O₃, Y₃Al₅O₁₂ (YAG), and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A heater assembly 148 is disposed in the interior volume 106 of the processing chamber 100 below the showerhead 130 or lid. The heater assembly 148 includes a support 150 that holds a substrate 144 during processing. The support 150 is attached to the end of a shaft 152 that is coupled to the chamber body 102 via a flange. The support 150, shaft 152 and flange may be constructed of a heater material containing AlN, for example, an AlN ceramic. The support 150 may further include mesas (e.g., dimples or bumps). The support may additionally include wires, for example, tungsten wires (not shown), embedded within the heater material of the support 150. In one embodiment, the support 150 may include metallic heater and sensor layers that are sandwiched between AlN ceramic layers. Such an assembly may be sintered in a high-temperature furnace to create a monolithic assembly. The layers may include a combination of heater circuits, sensor elements, ground planes, radio frequency grids and metallic and ceramic flow channels.

A metal fluoride coating in accordance with embodiments described herein may be deposited on at least a portion of a surface of any of the chamber components described herein (and those that may not be illustrated in FIG. 1), which may be exposed to processing chemistry used within the processing chamber. Exemplary chamber components that may be coated with a metal fluoride coating described herein include, without limitation, an electrostatic chuck, a nozzle, a gas distribution plate, a shower head (e.g., 130), an electrostatic chuck component, a chamber wall (e.g., 108), a liner (e.g., 116), a liner kit, a gas line, a chamber lid, a nozzle, a single ring, a processing kit ring, edge ring, a base, a shield, a plasma screen, a flow equalizer, a cooling base, a chamber viewport, a bellow, any part of a heater assembly (including the support 150, the shaft 152, the flange), faceplate, blocker plate, and so on.

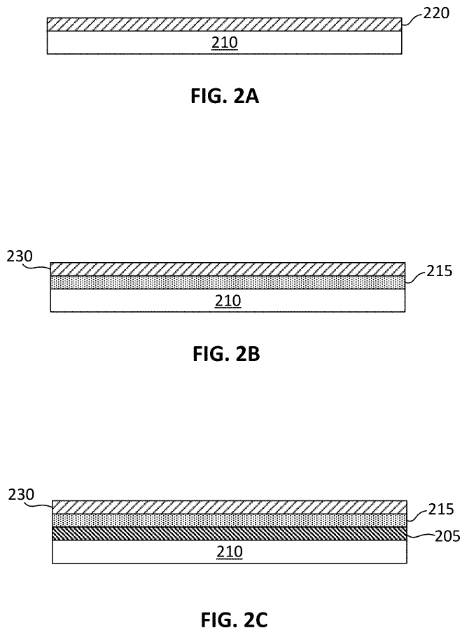

FIGS. 2A-2C depict a cross-sectional view of an article 210 having a metal fluoride coating thereon according to various embodiments contemplated herein. The article 210 may be made out of a ceramic (e.g., an oxide based ceramic, a nitride based ceramic, or a carbide based ceramic), a metal (e.g., a bulk metal, nickel, pure nickel, carpenter nickel (Ni 200/201), stainless steel, titanium and/or combinations thereof), or a metal alloy, quartz, or combinations thereof and/or combinations thereof. Examples of oxide based ceramics include SiO₂ (quartz), Al₂O₃, Y₂O₃, and so on. Examples of carbide based ceramics include SiC, Si—SiC, and so on. Examples of nitride-based ceramics include AN, SiN, and so on. In some embodiments, article 210 may be aluminum, anodized aluminum, an aluminum alloy (e.g., Al 6061), or an anodized aluminum alloy. In some embodiments, article 210 may be stainless steel, nickel, a nickel-chromium alloy, anaustenitic nickel-chromium-based superalloys (e.g., Inconel®), iron, cobalt, titanium, magnesium, copper, zinc, chromium and the like. The term “substrate,” “article”, “chamber component” may be used interchangeably herein.

As depicted in FIGS. 2A-2C, at least a portion of the surface of article 210 may be coated with a metal fluoride coating according to embodiments herein. In embodiments, the metal fluoride coating may be a conformal coating, which may be a converted metal fluoride coating formed by performing a plating process (e.g., via electroplating) to form a metal layer and then exposing the metal layer to fluorine to convert the metal layer into a metal fluoride layer. The conformal metal fluoride coating may provide complete or partial coverage of the underlying surface that is coated (including coated surface features) with a uniform thickness having a thickness variation of less than about +/−20%, a thickness variation of less than about +/−10%, a thickness variation of less than about +/−5%, or a lower thickness variation, as measured by comparing the thickness of the corrosion resistant coating at one location with the thickness of the corrosion resistant coating at another location (or as measured by obtaining the thickness of the corrosion resistant coating at a plurality of locations and calculating the standard deviation of the obtained thickness values).

In embodiments, the metal fluoride coating (e.g., 220 and 230) may include at least one metal fluoride having a formula of M1ₓF_{w}, M1ₓM2_{y}F_{w}, M1ₓM2_{y}M3_{z}F_{w} and/or combinations thereof. In embodiments when the metal fluoride formula is M1ₓF_{w}, x is 1, and w ranges from 1 to 3. In embodiments, when the metal fluoride formula is M1ₓM2_{y}F_{w}, x ranges from 0.1 to 1, y ranges from 0.1 to 1, and w ranges from 1-3. In embodiments when the metal fluoride formula is M1ₓM2_{y}M3_{z}F_{w}, x ranges from 0.1 to 1, y ranges from 0.1 to 1, z ranges from 0.1 to 1, and w ranges from 1 to 3. The values for x, y, z, and w may be whole numbers or fractions. The ranges for x, y, z, and w are inclusive of the end values (i.e., inclusive of 0.1 and 1 for x, y, and z and of 1 and 3 for w). The ranges for x, y, z, and w also encompass every single value falling within the specified ranges and any sub-range falling within the specified ranges, whether a whole number of or a fraction. For instance, x, y, and z may independently be, without limitations, about 0.1, about 0.2, about 0.3, about 0.4, about 0.5, about 0.6, about 0.7, about 0.8, about 0.9, or about 1. Similarly, w may be, without limitations to whole numbers only (since fractions are also possible), about 1, about 2, or about 3.

In the metal fluoride formulas, M1, M2, and M3 each represent a different metal. Exemplary suitable metals for M1, M2, and M3 include, without limitations, nickel, magnesium, aluminum, cobalt, chromium, yttrium, titanium, silver, gold, iron and/or zinc. In certain embodiments, at least one of M1, M2, and M3 is nickel. Exemplary metal fluoride coatings as defined above may include at least one of NiₓF_{w}, NiₓP_{y}F_{w} and/or NiₓAu_{y}Ag_{z}F_{w}. Without being construed as limiting, nickel-containing metal fluorides are believed to be suitable metal fluoride coating candidates because the reaction product of a nickel component with a fluorine containing chemistry (e.g., a fluorine containing plasma) is believed to have a lower vapor pressure than the vapor pressure of the reaction product of the substrate material with fluorine containing plasma (e.g, the reaction product of aluminum with fluorine). For instance, the vapor pressure of AlF₃ ranges from about 0.001 Torr to about 1000 Torr at temperatures of about 750° C. to about 1250° C. In comparison, the vapor pressure of NiF₂ ranges from about 0.001 Torr to about 0.1 Torr at temperature range of 1000° C. to about 1250° C. and only reaches 1000 Torr at a temperature as high as about 2250° C.

In embodiments, where the substrate contains aluminum or an aluminum alloy, exposure of the substrate to fluorine-containing processing gases, plasma or HF cleaning chemicals at an elevated temperatures such as 400° C. to 1000° C., the aluminum may react with the fluorine in the processing gases to form AlFₓ species that are highly volatile due to their high vapor pressure at the exemplified temperature range. Forming a metal fluoride coating on an aluminum-based article, where the metal fluoride coating includes a metal fluoride formula as described herein is believed to reduce the number of particles that are generated for several reasons. Because the metal fluoride coating is already fluorinated, it is believed that fluorine from the processing environment is less likely to attack the coating. Furthermore, the metal fluoride coating and its reaction products with the fluorine from the processing environment (if any) are believed to have a lower vapor pressure than the vapor pressure of potential reaction products of the material of the underlying article with the fluorine (e.g., AlFₓ species). Hence, if any reaction occurs between components of the metal fluoride coating and the fluorine in the processing environment, the products from such reaction are less likely to sublime and deposit elsewhere within the chamber.

In embodiments, as depicted in FIG. 2A, an article 210 (e.g., a bulk metal, a metal alloy, etc.) may contain a metal fluoride coating 220 on a surface thereof. In embodiments, the article 210, which may contain a metal, may be contacted with fluorine gas or fluorine radicals as described herein to form the metal fluoride coating 220 having a desired thickness and crystalline structure. For example, the surface of the article 210 being coated (e.g., a process chamber component) may be a metal body (e.g., nickel, nickel alloy) and the metal fluoride coating may be at least one of NiₓF_{w}, NiₓP_{y}F_{w} or NiₓAu_{y}Ag_{z}F_{w}. In embodiments, if the article 210 is a bulk nickel material, it may be contacted with fluorine gas or fluorine radicals to convert Ni at the surface of the article to NiₓF_{w}, for example, where x is 1 and y is 2.

In embodiments, as depicted in FIG. 2B, the metal fluoride coating may include an electroless metal plated coating layer or an electrolytic metal plated coating layer (collectively referred to as “the metal plated coating layer”) 215 on the surface of the article 210 (e.g., a bulk metal, a metal alloy, a ceramic, etc.). The metal plated coating layer 215 may be formed on the article 210 to improve the performance of the article 210 in high temperature applications (e.g., at temperatures higher than those required for sputtering resistance). For example, nickel has mechanical properties, that is, physical properties exhibited upon application force (e.g., modulus of elasticity, tensile strength, elongation, hardness, fatigue limit, etc.), that exceeds other metals (e.g., aluminum, other metals and alloys used in low temperature applications). Metal plated coating layer 215 may be used in applications with temperatures up to about 800° C. for bulk metal substrates and up to about 1,000° C. if the substrate is ceramic. In embodiments, the metal plated layer may have a thickness of about 1 μm to about 50 μm, or about 5 μm to about 45 μm, or about 10 μm to about 40 μm, or about 15 μm to about 35 μm, or about 20 μm to about 30 μm, or any individual thickness or sub-range within these ranges. The metal plated coating layer 215 may be contacted with a fluorine gas or fluorine radicals to convert metal at the surface of the metal plated coating layer 215 to metal fluoride(s) to form the metal fluoride coating 230. The reaction temperature, time of exposure and flow rate of the fluorine gas or fluorine radicals may be adjusted to achieve a desired metal fluoride coating thickness and crystalline structure according to embodiments herein.

In embodiments, as depicted in FIG. 2C, the metal fluoride coating may include an intermediate layer 205 on a surface of article 210 (e.g., a bulk metal, a metal alloy, a ceramic, etc.). The intermediate layer 205 may be configured to improve the adhesive strength between the surface of the article 210 and a metal plated coating layer 215. The intermediate layer 205 may also be configured to relax stress, e.g., by having a coefficient of thermal expansion (CTE) value that is between the CTE of the metal plated coating layer and the CTE of the article to mitigate any potential mismatch in the CTE between the article and the metal plated coating layer. In such embodiment, the intermediate layer mitigates the CTE differential between the metal plated coating layer and the article 210 (e.g., a process chamber component) to reduce the coating's susceptibility to cracking upon thermal cycling which could result from a CTE mismatch.

The intermediate layer 205 may also be configured as a diffusion barrier layer that blocks fluorine containing species (such as fluorine radicals) from diffusing from the processing environment in the semiconductor processing chamber or from the fluorine containing metal fluoride coating all the way to the underlying article (e.g., through grain boundaries in the metal fluoride coating). In certain embodiments, the intermediate layer 205 may be amorphous, such as amorphous alumina, or amorphous yttrium aluminum garnet (YAG). The boundary between the intermediate layer 205 and the underlying article 210 and/or between the intermediate layer 205 and the metal plated coating layer 230 deposited thereon may be discrete or not-discrete (e.g., the metal fluoride coating and adhesion layer and/or the article and the adhesion layer may be intermixed/interdiffused/integral). Metal plated coating layer 215 may be contacted with a fluorine gas or fluorine radicals to convert metal at the surface of the metal plated coating layer 215 to metal fluoride(s) to form the metal fluoride coating 230. The reaction temperature, time of exposure and flow rate of the fluorine gas or fluorine radicals may be adjusted to achieve a desired metal fluoride coating thickness and crystalline structure according to embodiments herein.

The thickness of the metal fluoride coating 220, 230 described herein may range from about 5 nm to about 5000 nm, from about 10 nm to about 4000 nm, from about 15 nm to about 3000 nm, from about 20 nm to about 2500 nm, from about 25 nm to about 2000 nm, from about 30 nm to about 1000 nm, about 50 nm, about 500 nm, or any sub-range of thickness or single value therein. The thickness and properties of the metal fluoride coating described herein depends on the parameters of the fluorine gas or fluorine radical conversion process according to embodiments herein. These properties may be tuned and adjusted in accordance with the intended application for the coated article.

In embodiments, the thickness of the metal plated coating layer 215 described herein may range from about 1 μm to about 50 μm, or about 5 μm to about 45 μm, or about 10 μm to about 40 μm, or about 15 μm to about 35 μm, or about 20 μm to about 30 μm, or any sub-range of thickness or single value therein. The thickness and properties of the metal plated coating layer 215 depends on the parameters of the electroless or electrolytic metal plating process according to embodiments herein. These properties may be tuned and adjusted in accordance with the intended application for the coated article.

In embodiments, the thickness of the intermediate layer 205 described herein may range from about 1 μm to about 50 μm, or about 5 μm to about 45 μm, or about 10 μm to about 40 μm, or about 15 μm to about 35 μm, or about 20 μm to about 30 μm, or any sub-range of thickness or single value therein. The thickness and properties of the intermediate layer 205 described herein depends on the parameters of the intermediate layer 205 deposition process. For example, according to embodiments, the intermediate layer 205 may be deposited by atomic layer deposition, chemical vapor deposition, physical vapor deposition, sputtering and/or combinations thereof.

In certain embodiments, the roughness of the metal fluoride coating 220, 230 ranges from about 0.1 microinches to 200 microinches, from about 0.5 microinches to about 50 microinches, from about 2 microinches to about 30 microinches, from about 5 microinches to about 20 microinches, from about 75 microinches to about 150 microinches, or from about 30 microinches to about 100 microinches, or any sub-range or single value therein. The roughness may be the arithmetic mean roughness (Rₐ) as measured by ASME B46.1.

In certain embodiments, the microhardness of the metal fluoride coating 220, 230 is greater than about 5 mN, greater than about 6 mN, greater than about 7 mN, greater than about 8 mN, greater than about 9 mN, greater than about 10 mN, greater than about 11 mN, or greater than about 12 mN. In certain embodiments, the microhardness of the metal fluoride coating 220, 230 is at least two times greater than the microhardness of stainless steel and/or at least 4 times greater than that of alumina. The above microhardness values may refer to the force exerted on the metal fluoride coating 220, 230 to observe a first failure (or first crack formation) of the metal fluoride coating. The microhardness may be measured using ASTM B578-87, E10, E18, E92 or E103 depending on the coating type.

In certain embodiments, the architecture and composition of the metal fluoride coating 220, 230 may be tuned to mediate the fluorine resistance of the metal fluoride coating and/or to slow down grain boundary attack by the fluorine in the processing chamber. In certain embodiments, a metal fluoride coating, such as the one depicted in FIG. 2A, or any of the other metal fluoride coatings described herein, may be subjected to post coating processing. Non-limiting exemplary post-coating processing includes ultrasonic cleaning of the metal fluoride coating with deionized water, cleaning in a bath of hydrofluoric acid and/or baking the substrate with the metal fluoride coating thereon. In embodiments, the metal fluoride coating 220, 230 may be baked by, for example, subjecting the metal fluoride coating to a temperature that ranges from about 100° C. to about 800° C., from about 200° C. to about 700° C., or from about 300° C. to about 600° C., or any single value or sub-range therein for a duration of about 2 hours to about 24 hours, about 4 hours to about 15 hours, or about 6 hours to about 12 hours, or any single value or sub-range therein. The baking temperature and duration may be selected based on the material of construction of the article, surface, and metal fluoride coating so as to maintain integrity and refrain from deforming, decomposing, or melting any or all of these components.

The composition of the various metal fluoride coatings may be tuned to achieve target coating properties based on the intended application for the coated article. For instance, a M1ₓF_{w} coating may include an M1 concentration of about 5 atom % to about 100 atom %, about 10 atom % to about 95 atom %, about 20 atom % to about 90 atom %, about 20 atom % and about 80 atom %, about 10 atom %, about 20 atom %, about 30 atom %, about 40 atom %, about 50 atom %, about 60 atom %, about 70 atom %, about 80 atom %, about 90 atom %, or any other range and/or number falling within these ranges, where the concentration is measured based on total amount of metal in the metal fluoride coating. When the concentration is measured based on the metal fluoride coating as a whole, the M1 concentration may be up to about 40 atom %, up to about 35 atom %, up to about 30 atom %, up to about 25 atom %, up to about 20 atom %, up to about 15 atom %, up to about 10 atom %, up to about 5 atom %, between about 20 atom % and about 45 atom %, or any other range and/or number falling within these ranges.

When the metal fluoride coating has the formula M1ₓM2_{y}F_{w}, the concentrations of the metals may be about 20-80 atom % M1 and 20-80 atom % M2, 30-70 atom % M1 and 30-70 atom % M2, 40-60 atom % M1 and 40-60 atom % M2, 50-80 atom % M1 and 20-50 atom % M2, or 60-70 atom % M1 and 30-40 atom % M2, where the concentrations of M1 and M2 are measured based on total amount of metal (M1+M2) in the metal fluoride coating. When the concentration is measured based on the metal fluoride coating as a whole, M1+M2 may together have a concentration of up to about 40 atom %, up to about 35 atom %, up to about 30 atom %, up to about 25 atom %, up to about 20 atom %, up to about 15 atom %, up to about 10 atom %, up to about 5 atom %, between about 20 atom % and about 45 atom %, or any other range and/or number falling within these ranges.

When the metal fluoride coating has the formula M1-M2_{y}M3_{z}F_{w}, the concentrations of the metals may be about 5-80 atom % M1 and 5-80 atom % M2 and 5-80 atom % M3, 10-70 atom % M1 and 10-70 atom % M2 and 10-70 atom % M3, 1-90 atom % M1 and 1-90 atom % M2 and 1-90 atom % M3, where the concentrations of M1, M2, and M3 are measured based on total amount of metal (M1+M2+M3) in the metal fluoride coating. When the concentration is measured based on the metal fluoride coating as a whole, M1+M2+M3 may together have a concentration of up to about 40 atom %, up to about 35 atom %, up to about 30 atom %, up to about 25 atom %, up to about 20 atom %, up to about 15 atom %, up to about 10 atom %, up to about 5 atom %, between about 20 atom % and about 45 atom %, or any other range and/or number falling within these ranges.

The fluorine concentration in the metal fluoride coatings described herein may be above 0 atom % up to about 95 atom %, from about 5 atom % to about 90 atom %, from about 10 atom % to about 85 atom %, from about 20 atom % to about 80 atom %, from about 40 atom % to about 75 atom %, or from about 50 atom % to about 70 atom %, or any other range and/or number falling within these ranges.

The resistance of the metal fluoride coating to plasma may be measured through “etch rate” (ER), which may have units of micron/hour (μm/hr) or Angstrom/hour (A/hr), throughout the duration of the coated components' operation and exposure to plasma (such as halogen or specifically fluorine plasma). Measurements may be taken after different processing times. For example, measurements may be taken before processing, or at about 50 processing hours, or at about 150 processing hours, or at about 200 processing hours, and so on. In one example, an electroless nickel plated coating that has been reacted with fluorine gas to form a metal fluoride coating, according to embodiments, were exposed to fluorine chemistry at a temperature of 650° C. for about 56 hours and showed no measurable coating loss. Variations in the composition of the metal fluoride coating deposited on the chamber components may result in multiple different plasma resistances or erosion rate values. Additionally, a metal fluoride coating with a single composition exposed to various plasmas could have multiple different plasma resistances or erosion rate values. For example, a plasma resistant material may have a first plasma resistance or erosion rate associated with a first type of plasma and a second plasma resistance or erosion rate associated with a second type of plasma.

In embodiments, further disclosed herein are methods for reducing particles during processing in a processing chamber. The methods may include contacting a substrate with fluorine to form a metal fluoride coating The metal fluoride coating may include at least one of a formula M1ₓF_{w}, wherein x has a value of 1 and w has a value from 1 to 3; a formula M1ₓM2_{y}F_{w}, wherein x has a value from 0.1 to 1, y has a value from 0.1 to 1, and w has a value from 1 to 3; or a formula M1ₓM2_{y}M3_{z}F_{w}, wherein x has a value from 0.1 to 1, y has a value from 0.1 to 1, z has a value from 0.1 to 1 and w has a value from 1 to 3, and wherein at least one of M1, M2, or M3 comprises nickel. In embodiments, M2 and M3 each independently may be a metal chosen from magnesium, aluminum, cobalt, chromium and/or yttrium.

In embodiments, the methods may further include depositing an electroless metal plated coating layer including nickel or an electrolytic metal plated coating layer including nickel on the substrate. The metal plated coating layer may be contacted with fluorine to form the metal fluoride coating. In embodiments, the electroless metal plated coating layer may include a nano-crystalline structure including tetragonal nickel phosphide (Ni₃P) and cubic Ni. In embodiments, the electroless metal plated coating layer or the electrolytic metal plated coating layer further comprises phosphorus (P), and wherein the metal fluoride coating is free of phosphorus.

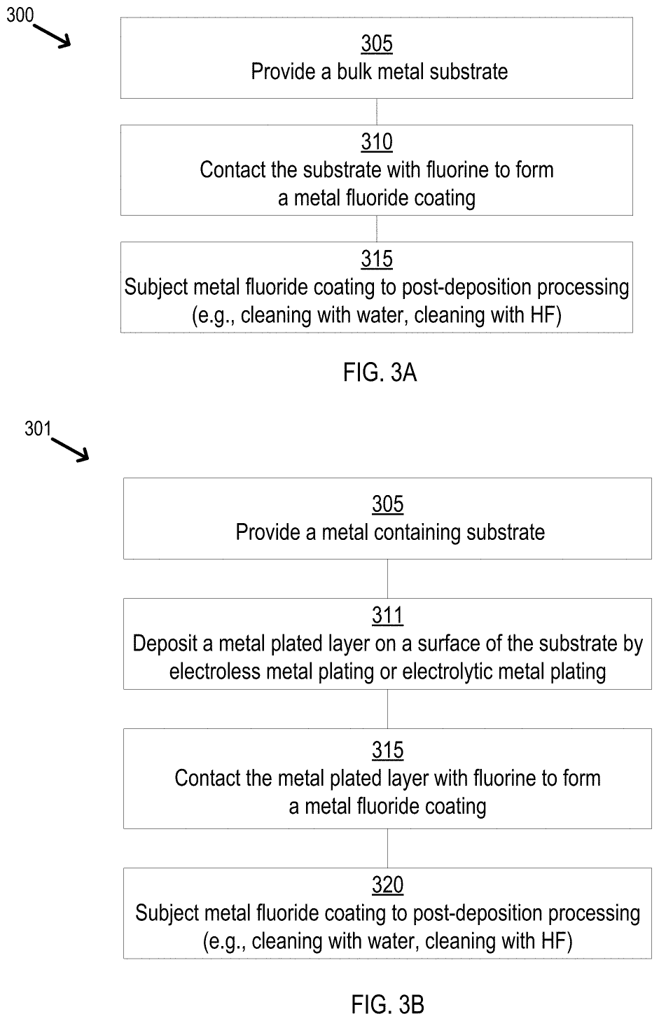

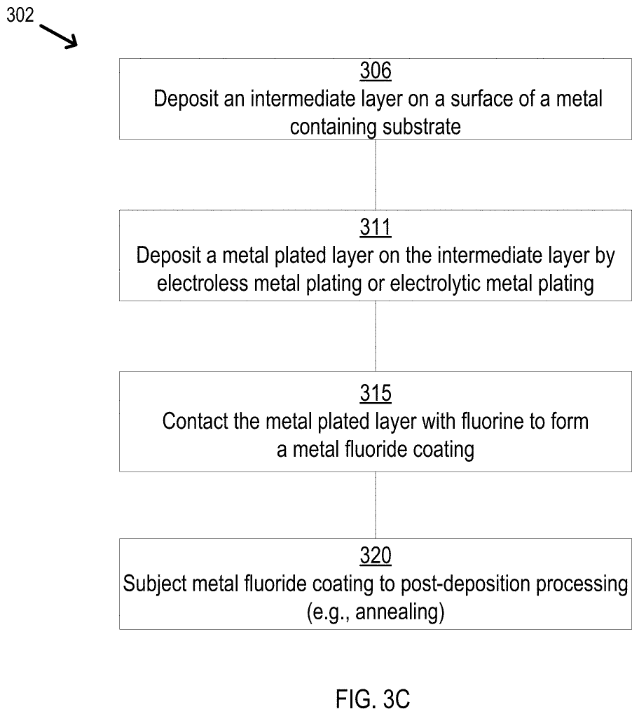

FIG. 3A discloses a method 300 for reducing particles during processing in a semiconductor processing chamber, in accordance with embodiments. In method 300, a substrate comprised of a bulk metal (e.g., a metal or metal alloy) and having at least a portion of one surface that may be exposed to an aggressive chemistry (e.g., halogen or fluorine based chemistry) that is commonly found within a processing chamber, is provided (305). At block 310, at least the portion of the substrate that may be exposed to aggressive chemistry and may be contacted with fluorine (e.g., from fluorine gas or fluorine radicals) to form a metal fluoride coating as described herein.

In embodiments, the contacting at block 310 may be include forming the metal fluoride coating using a thermal molecular fluorine gas (F₂) conversion (Ni+F₂=NiF₂) process. The thermal molecular fluorine gas conversion process may include pre-wet cleaning (e.g., using hydrofluoric acid, nitric acid or a combination thereof) and baking out a thermal reactor (e.g., at a temperature of about 25° C. to about 90° C.). The substrates (e.g., parts and/or components) to be reacted with the fluorine gas are loaded into the reactor. The reactor may be placed under vacuum, for example, to a pressure of about 10 mTorr to about 50 mTorr. Once evacuated, the temperature within the reactor may be increased to about 100° C. to about 500° C. depending on the material of the substrate within and the desired coating thickness. Notably, a higher temperature may cause the metal fluoride coating to grow (i.e., thicken) at a faster rate than at a lower temperature, which may affect the crystalline structure of the metal fluoride coating. When the metal fluoride coating is formed at a temperature of about 300° C., the resulting thickness of the coating may be about 200 nm. The thickness of the coating may be increased, at the same temperature, if exposed to the fluorine gas for a longer period. At about 100° C., it would take longer to form a 200 nm coating than at 300° C.

The underlying substrate material may also affect the crystalline structure of the metal fluoride coating. In embodiments, the grain size may be function of temperature—a higher temperature results in a relatively larger grain size.

An inert gas such as argon or nitrogen may be introduced into the evacuated chamber to assist in stabilizing the temperature over a period of about 1 hour to about 10 hours. Fluorine gas may be introduced into the evacuated and temperature controlled reactor at a flow rate of about 0.05 nm/min to about 1.0 nm/min, or about 0.1 nm/min to about 0.5 nm/min, or about 0.2 nm/min, 0.28 nm/min or about 0.3 nm/min for about 1 sec to about 24 hours, or about 1 min to about 12 hours, or about 10 min to about 6 hours, or about 30 min to about 3 hours, or any single value or sub-range therein. Upon completion of the reaction, the flow of fluorine gas may be stopped while the inert gas continues to flow into the reactor. Meanwhile, the temperature may be reduced at a controlled ramping rate of about 0.5° C./min to about 5° C./min. In embodiments, if the temperature is reduced too fast, then the metal fluoride coating may peel away from the underlying surface. In embodiments, if the coating is relatively thick (e.g., about 5 μm) and the temperature is reduced too fast, the coating may peel away and crack. If the coating is a metal fluoride, and the substrate is nickel, these materials have different thermal expansions, so if the temperature is dropped too fast, then there will be some relative stress between the two materials, which can cause the cracking and peeling.

When the temperature within the reactor reaches about room temperature, the substrates having the metal fluoride coating may be removed from the reactor. The coated substrates may be cleaned using deionized water ultrasonic cleaning. The cleaned coated substrates may be baked at a temperature of about 25° C. to about 90° C. for about 30 min to about 600 min and then packaged.

In some embodiments, the contacting at block 310 may be include forming the metal fluoride coating using a fluorine radical (F*) conversion (Ni+2F=NiF₂) process. The fluorine radical conversion process may include pre-wet cleaning (e.g., using hydrofluoric acid, nitric acid or a combination thereof) and baking out the reactor (e.g., at a temperature of about 25° C. to about 90° C.). The substrates (e.g., parts and/or components) to be reacted with the fluorine gas are loaded into the reactor. The reactor may be placed under vacuum, for example, to a pressure of about 10 mTorr to about 50 mTorr. Once evacuated, the temperature within the reactor may be increased to about 100° C. to about 500° C. depending on the material of the substrate within and the desired coating thickness. An inert gas such as argon or nitrogen may be introduced into the evacuated chamber to assist in stabilizing the temperature over a period of about 1 hour to about 10 hours. Fluorine radicals from a Remote Plasma Source (RPS) may be introduced into the evacuated and temperature controlled reactor at a controlled flow rate of about 0.01 nm/min to about 1.0 nm/min, about 0.05 nm/min to about 0.5 nm/min, or about 0.04 nm/min, about 0.05 nm/min, about 0.06 nm/min, about 0.07 nm/min, about 0.08 nm/min, or about 0.09 nm/min for about 1 sec to about 24 hours, or about 1 min to about 12 hours, or about 10 min to about 6 hours, or about 30 min to about 3 hours, or any single value or sub-range therein. Upon completion of the reaction, the flow of fluorine radicals may be stopped while the inert gas continues to flow into the reactor. Meanwhile the temperature may be reduced at a controlled ramping rate of about 0.5° C./min to about 5° C./min. When the temperature within the reactor reaches about room temperature, the substrates having the metal fluoride coating may be removed from the reactor. The coated substrates may be cleaned using deionized water ultrasonic cleaning. The cleaned coated substrates may be baked at a temperature of about 25° C. to about 90° C. for about 30 min to about 600 min and then packaged.

Notably, a higher temperature may cause the metal fluoride coating to grow (i.e., thicken) at a faster rate than at a lower temperature, which may affect the crystalline structure of the metal fluoride coating. When the metal fluoride coating is formed at a temperature of about 300° C. for a period of about 12 hours, the resulting thickness of the coating may be about 50 nm. The thickness of the coating may be increased, at the same temperature, if exposed to the fluorine gas for a longer period. At about 100° C., it would take longer to form a 50 nm coating than at 300° C.

At block 315, the substrate having the metal fluoride coating thereon may be subjected to post-deposition processing as described herein. Non-limiting exemplary post-coating processing includes ultrasonic cleaning of the metal fluoride coating with deionized water, cleaning in a bath of hydrofluoric acid and/or baking the substrate having the metal fluoride coating. In embodiments, the metal fluoride coating may be baked by, for example, subjecting the metal fluoride coating to a temperature that ranges from about 100° C. to about 800° C., from about 200° C. to about 700° C., or from about 300° C. to about 600° C., or any single value or sub-range therein for a duration of about 2 hours to about 24 hours, about 4 hours to about 15 hours, or about 6 hours to about 12 hours, or any single value or sub-range therein. The baking temperature and duration may be selected based on the material of construction of the article, surface, and metal fluoride coating so as to maintain integrity and refrain from deforming, decomposing, or melting any or all of these components.

FIG. 3B discloses a method 301 for reducing particles during processing in a semiconductor processing chamber, in accordance with embodiments. In method 301, a substrate comprised of a metal (e.g., a metal or metal alloy) or a ceramic and having at least a portion of one surface that may be exposed to an aggressive chemistry (e.g., halogen or fluorine based chemistry) that is commonly found within a processing chamber, is provided (305). At block 311, a metal plated coating layer may be deposited onto at least the portion of the substrate that may be exposed to aggressive chemistry and may be contacted with fluorine (e.g., from fluorine gas or fluorine radicals).

In embodiments, depositing the metal plated layer at block 311 may be by an electroless metal plating process or an electrolytic metal plating process as described herein. The substrate may be coated with, for example, an electroless metal plated coating layer following a process for the electroless deposition of a coating (e.g., a nickel-phosphorous coating) on metallic or ceramic components used in corrosive environments that contain corrosive chemicals. The electroless metal plating process can form a coating directly on a bulk metal-containing (or ceramic) substrate or on an intermediate layer formed on the surface of the substrate. The electroless metal plating process does not need electric current, so the electroless metal plated coating can be deposited on any suitable substrate including an insulator surface.

In embodiments, the method for electroless deposition may be partly based on ASTM B 656, B 733. In embodiments, the electroless deposition method may include a scheme, in accordance with ASTM B 733, to select adequate post plating heat treatment for each type of metal to increase coating adhesion. The following materials may be used in an electroless metal plating process (e.g., to plate a nickel-phosphorous coating):
De-ionized (DI) water: The source of de-ionized water may have a specific resistivity of no less than 16 M Ohm-cm as determined in accordance with ASTM D1125. A proper UV light module may be installed for bacteria control. At point of use, DI water used for rinsing and cleaning may have a minimum specific resistivity of 2.0 M Ohm-cm.
Chemicals: Incoming chemicals may be monitored for mobile ion/heavy metal levels. Maximum acceptable levels for ion contamination and heavy metals may be established which correlate to the requirements listed in Table 1 with maintained records indicating incoming chemical purity.

TABLE 1
Summary of targets for exemplary electroless nickel-phosphorous plating

| TARGETS | ACCEPTANCE CRITERIA |
|---|---|
| Coating Thickness | 0.0010 to 0.0012 inch |
| Adhesion | No blistering or other evidence of poor |
| | adhesion shall be observed at 4x |
| | magnification. |
| Porosity | No red spots shall be observed. |
| Example Nickel-Phosphorous | 10 to 12 wt. % |
| Coating Composition - | |
| Phosphorous Content | |
| Nitric Acid Test | No discoloration. |
| Corrosion Resistance | a. 24 hours screening test: No blistering, |
| | pitting and discoloration. |
| | b. 22 days continuous exposure: No |
| | blistering, pitting and discoloration. |
| Microhardness | 400 to 525 HK |
| Outgassing (μg/cm2) | Total Mass Loss (TML) ≤ 0.115 |
| | Mass Loss of Species with Very High |
| | Volatility |
| | (MLVH) ≤ 0.055 |
| | Sub-sum ≤ 0.060 |
| Ionic Contamination, | F-, ≤ 30 |
| Surface Concentration | Cl-, ≤ 470 |
| (1012 Molecules/cm2) | NO2-, ≤ 100 |
| | Br-, ≤ 8 |
| | NO3-, ≤ 155 |
| | SO4-2, ≤ 55 |
| | PO4-3, ≤ 120 |
| Ionic Contamination, | Li+, ≤ 90 |
| Surface Concentration | Na+, ≤ 125 |
| (1012 Molecules/cm2) | NH4+, ≤ 130 |
| | K+, ≤ 70 |
| | Mg+2, ≤ 10 |
| | Ca+2, ≤ 400 |
| Black Light Inspection | No fluorescence, fibers or particles shall be |
| | observed on surfaces exposed to black light. |
| Interface Integrity | No interfacial discontinuity, porosity and |
| | entrapment |

Blasting Media: Aluminum Oxide, Al₂O₃, may be used unless otherwise specified. The use of garnet is prohibited unless otherwise specified. The cleanliness and effectiveness of such media may be controlled so the processed components will meet the requirements specified in this specification.
Nitrogen or Air: Nitrogen or air used to dry parts must be dry, oil-free, and filtered at the point of use with a 0.1 μm filter. The filters may be replaced regularly and a maintenance record may be documented.

Following formation of the ENP coating, the resulting coated substrate may be cleaned using the following scheme:

Clean parts in ultrasonic cleaner at 130°+/−2 F for 2 min.

Clean parts in Aluminum Soak (or equivalent chemical) at 130°+/−2 F for 2 min.

Rinse parts in D.I. tank at ambient for 30 sec.

Rinse parts in D.I. tank at 120°+/−2 F for 30 sec.

Rinse parts in D.I. tank at 140°+/−2 F for 30 sec.

Rinse parts in Cleanroom Ultrasonic rinse D.I. at 140°+/−2 F for 30 sec.

Compress air/N2 blow dry in cleanroom.

In some embodiments, depositing the metal plated layer at block 311 may be by an electrolytic metal plating process or an electrolytic metal plating process as described herein. a substrate may be coated following the manufacture process, material and performance evaluation specifications for nickel, silver and gold plating (e.g., of a copper C101 or BeCu25 alloy substrate). An exemplary electrolytic plated coating may contain nickel, silver and gold. The coating may be applied on any substrate as described herein including a high purity copper or copper alloy surface including C101 and BeCu25 or other materials. The electrolytic plating may be applied on chamber critical components such as a heater RF strap and faceplate/gas box RF strap. The following materials and specifications may be used in the process to prepare ENP coatings:
De-ionized (DI) water: At point of use, DI water used for rinsing and cleaning (except for drag out rinse) may have a minimum specific resistivity of 2.0 M Ohm-cm.
Chemicals: Incoming chemicals may be monitored for mobile ion/heavy metal levels by trace metal measurement such as ICP-MS (ion capacitive plasma mass spectroscopy). Maximum acceptable levels for ion contamination and heavy metals shall be established with maintained records indicating incoming chemical purity.
Masking Materials: Masking materials used to mask components may be monitored for mobile ion contamination. Masking line definition variation <±0.010 inch may be used.
Nitrogen or Air: Nitrogen or air used to dry components may be dry, oil-free, and filtered at the point of use with a 0.1 μm filter. The filters may be replaced regularly and a maintenance record may be documented.
Gloves and Wipes: Gloves, wipes or other materials used for handling components and wet processes may be used.
Packaging Materials: Suitable packaging materials may be used.

In embodiments, the process for coating a substrate, prior to forming the metal fluoride coating, may be an electrolytic plating wet chemistry process performed with equipment capable of monitoring, controlling and recording all parameters that affect product quality. Such parameters include, but are not limited to, processing time, temperature, compositions of chemistry, concentration of the chemistry, voltages and current densities, method of rinsing, resistivity of rinsing water and operations of ultrasonic equipment, frequency of ultrasonic tool, etc.

TABLE 2
Plating properties for an exemplary nickel, silver and gold coating

| | | | | Frequency of |
|---|---|---|---|---|
| Parameter | Requirement | Methodology | Test bed | test |
| Coating thickness | Ni 2 +/− 0.5 um for heater | SEM cross- | Witness | Every |
| (follow drawing call- | RF strap and gas box/FP | section | Coupon | Chemistry |
| out, if no drawing | RF strap; Au 15 +/− 5 um | | | Changing in |
| call-out, follow here) | for heater RF strap, and 36 | | | Tank |
| | +/− 5 um for gas box/FP RF | | | |
| | strap | | | |
| Porosity (image | <0.1% | Image Pro & | Witness | Every |
| software and cross- | | SEM cross- | Coupon | Chemistry |
| section SEM) | | section | | Changing in |
| | | | | Tank |
| Thermal treatment | Air oven @ 325 C. for 24 | Visual and | Witness | Every |
| for heater RF strap | hrs, no Cu and Ni diffused | SEM/EDX | Coupon | Chemistry |
| (2um underneath Ni | out | | | Changing in |
| and 15um top Au on | | | | Tank |
| BeCu25 substrate) | | | | |
| Thermal treatment | Air oven @ 200 C. for 24 | Visual and | Witness | Every |
| for gas box/FP RF | hrs, no Cu and Ni diffused | SEM/EDX | Coupon | Chemistry |
| strap (2um | out | | | Changing in |
| underneath Ni and | | | | Tank |
| 36um top Ag on Cu | | | | |
| C101 substrate) | | | | |
| Coating composition | No P, S, F, Cl and Br | EDX @ 5KV | Witness | Every |
| | detected, and no other | accelerating | Coupon | Chemistry |
| | elements detected except | voltage | | Changing in |
| | Au, O, C and N, EDX | | | Tank |
| | analysis from plating | | | |
| | surface at 5KV accelerate | | | |
| | voltage. Au plating C < 10 | | | |
| | wt %, O < 2 wt % and N < 2 | | | |
| | wt %. | | | |
| Pin hole and voids | Not allowed | Visual | Product | Every part |
| Post plated surface | Per drawing call-out if | Profilometer | Product | Every part |
| Ra | applicable | | | |

In embodiments, pre-cleaning may be applied to the incoming part prior to the electrolytic plating process to enable the highest coating quality. Chemical bathes may be monitored regularly for adequate control of chemical composition, concentration, pH value, and level of metallic impurities. All chemical baths may be filtered and shall be free of any visible surface films or scums. Tanks may be covered when not in use. Chemical bathes and DI water in immersion tanks may be agitated by oil-free clean dry air or nitrogen. Mechanical agitation may be configured to prevent contamination by particles or hydrocarbons. DI water may be used for various stages of rinsing using: a) rinse by spray or immersion is acceptable by using cold DI water with specific resistivity of no less than 200 K Ohm-cm; b) by power spray blind holes, creases, and non-welded seams by using cold DI water with specific resistivity of no less than 2 M Ohm-cm; or c) hot rinse by immersion in a hot DI bath of 38 to 46° C. (100 to 115° F.) with minimum resistivity of 4 M Ohm-cm. DI water in immersion tanks may be overflowing.

In embodiments, the contacting at block 315 may include forming the metal fluoride coating using a thermal molecular fluorine gas (F₂) conversion (Ni+F₂=NiF₂) process according to embodiments described herein. For example, the metal plated coating may be contacted with fluorine gas to form the metal fluoride coating. In some embodiments, the contacting at block 315 may be include forming the metal fluoride coating using a fluorine radical (F*) conversion (Ni+2F*=NiF₂) process according to embodiments described herein. For example, the metal plated coating may be contacted with fluorine radicals to form the metal fluoride coating. At block 320, the substrate having the metal fluoride coating thereon may be subjected to post-deposition processing as described herein.

FIG. 3C discloses a method 302 for reducing particles during processing in a semiconductor processing chamber, in accordance with embodiments. In method 302, a substrate comprised of a metal (e.g., a metal or metal alloy) or a ceramic and having at least a portion of one surface that may be exposed to an aggressive chemistry (e.g., halogen or fluorine based chemistry) that is commonly found within a processing chamber, may be provided. At block 306, an intermediate layer according to embodiments herein may be deposited on a surface of the substrate. The intermediate layer may be deposited using atomic layer deposition, chemical vapor deposition, physical vapor deposition, sputtering and/or combinations thereof.

At block 311, a metal plated coating layer may be deposited onto at least the portion of the substrate that may be exposed to aggressive chemistry and may be contacted with fluorine (e.g., from fluorine gas or fluorine radicals). In embodiments, the metal plated coating layer may be deposited by electroless metal plating or electrolytic metal plating as described with respect to FIG. 3B.

In embodiments, the contacting at block 315 may include forming the metal fluoride coating using a thermal molecular fluorine gas (F₂) conversion (Ni+F₂=NiF₂) process according to embodiments described herein. For example, the metal plated coating deposited on the intermediate layer may be contacted with fluorine gas to form the metal fluoride coating. In some embodiments, the contacting at block 315 may include forming the metal fluoride coating using a fluorine radical (F*) conversion (Ni+2F*=NiF₂) process according to embodiments described herein. For example, the metal plated coating deposited on the intermediate layer may be contacted with fluorine radicals to form the metal fluoride coating. At block 320, the substrate having the metal fluoride coating thereon may be subjected to post-deposition processing according to embodiments herein.

### ILLUSTRATIVE EXAMPLES

The following examples are set forth to assist in understanding the disclosure and should not be construed as specifically limiting the disclosure described and claimed herein. Such variations of the disclosure, including the substitution of all equivalents now known or later developed, which would be within the purview of those skilled in the art, and changes in formulation or minor changes in experimental design, are to be considered to fall within the scope of the disclosure incorporated herein.

### Example 1—NiF₂ Coating Formed by a Thermal Fluorine Gas Conversion Process

Exemplified herein is a metal fluoride coating of the formula M1ₓF_{w}, where M1 is Ni. This metal fluoride coating was deposited using a thermal fluorine gas (F₂) conversion (Ni+F₂=NiF₂) process according to embodiments herein.

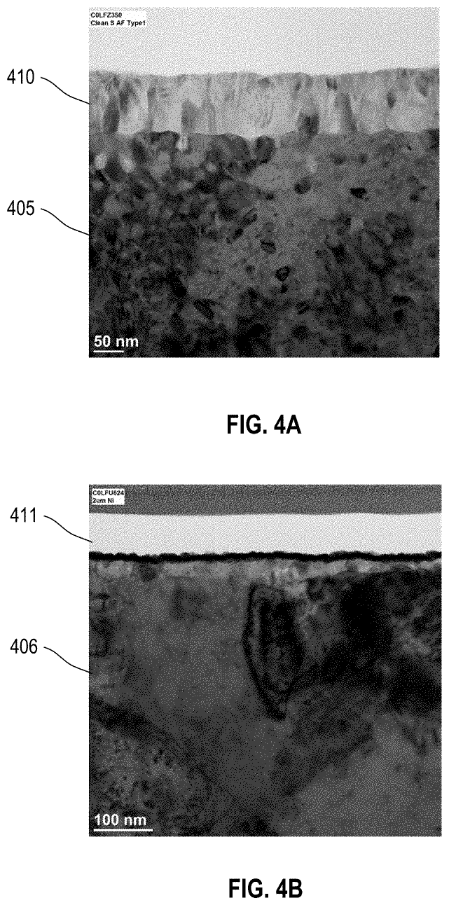

FIG. 4A depicts a cross sectional view of an article coated with the above-described metal fluoride coating (i.e., NiF₂ on an electroless nickel plated or “ENP” coating layer), according to an embodiment, as viewed by a scanning electron microscope (SEM) at 50 nm scale. From the SEM image, it was observed that the NiF₂ coating was dense and crystalline. It was further observed that the metal fluoride coating was tightly combined with the underlying electroless nickel plated coating and was free of any voids or pores at the interface between the metal fluoride coating and the ENP coating. It was also observed that phosphorus present in the ENP did not diffuse into the NiF₂ coating layer or onto the surface of the NiF₂ coating layer. Additionally, from the SEM image, it was observed that the ENP coating layer changed to nanocrystalline with about a 10 nm to about a 40 nm grain size. The crystalline structure of the NiF₂ coating was tetragonal (P42/mnm) and the ENP layer changed to nano-crystalline Ni₃P (Nickel Phosphide, tetragonal) and Ni (cubic).

### Example 2—NiF₂ Coating Formed by a Fluorine Radical (F*) Conversion Process

Exemplified herein is a metal fluoride coating of the formula M1ₓF_{w}, where M1 is Ni. This metal fluoride coating was deposited using a fluorine radical (F*) conversion (Ni+2F=NiF₂) process according to embodiments herein.

FIG. 4B depicts a cross sectional view of an article coated with the above-described metal fluoride coating, according to an embodiment, as viewed by a scanning electron microscope (SEM) at 100 nm scale. From the SEM image, it was observed that the NiF₂ coating was dense and crystalline. It was further observed that the metal fluoride coating was tightly combined with the underlying ENP coating and was free of any voids or pores at the interface between the metal fluoride coating and the ENP coating. Additionally, from the SEM image it was observed that the ENP coating was sub-micron crystalline with an about 200 nm to about 500 nm grain size. It was also observed that phosphorus present in the ENP did not diffuse into the NiF₂ coating or onto the surface of the coating. The crystalline structure of the NiF₂ coating was tetragonal (P42/mnm) and the ENP layer changed to nano-crystalline Ni₃P (Nickel Phosphide, tetragonal) and Ni (cubic).

### Example 3—Nitrogen Trifluoride Cleaning Test of Various Materials

Coupons were prepared according to the parameters described in Table 3. The coupons were exposed to nitrogen trifluoride gas within a reactor chamber. The internal temperature of the reactor chamber was set and controlled to 300° C. by a heater. Each coupon was directly loaded onto the heater surface while the NF₃ cleaning recipe shown in Table 4 was performed within the chamber. The cleaning test was conducted for a total of 48 hours and about 10 RF ON hours.

Observations made by SEM and XPS for each coupon is shown in Table 3. As indicated in Table 3, after the NF₃ test, the amount of phosphorus (P) was largely reduced due to the formation of PF₃ gas. F* easily reacts with P to form PF₃ gas, which has a Gibbs formation free energy of −897.5 kJ/mol, a stable compound. Phosphorus trifluoride (formula PF₃), is a colorless and odorless gas. In an electroplated nickel coating surface, Ni can react with HE, but not with H₂O, also P in the electroless Ni plated coating reacts with HF therefore the metal plated coating is not stable in HF. Pure Ni can react with HF, but not with H₂O and therefore pure Ni is not stable in HF. In comparison, coatings of NiF₂ do not react with HF or H₂O and therefore NiF₂ is stable in RF and H₂O.

These above-mentioned thermodynamic characteristics indicate that NiF₂ coatings can be cleaned using deionized water. Nickel(II) fluoride coatings react with strong bases to make nickel(II) hydroxide, a green colored compound as follows: NiF₂+2 NaOH→Ni(OH)₂+2 NaF. Additionally, NiF₂ coatings are soluble in acid.

TABLE 3
Coupon parameters and cleaning results

| | | | | Fluorine | |
|---|---|---|---|---|---|
| | | Post-Clean | | Level After | SEM and XPS |
| Coupon | Pre-Weight | Weight | Weight | NF₃ | Observations After |
| Description | (g) | (g) | Loss (%) | (Vol %) | NF₃ Clean |
| Bare A16061 | 3.1121 | 3.1128 | -0.2 | 28.4 | Surface was |
| | | | | | damaged and |
| | | | | | discoloration; high |
| | | | | | fluoride content |
| | | | | | formed; high |
| | | | | | magnesium (Mg) |
| | | | | | content diffused out |
| Dual Ni (DNP) | 16.7732 | 16.7736 | 0.00 | 38.7 | Snow flower |
| | | | | | patterns formed; |
| | | | | | discoloration; NiF₂ |
| | | | | | formed on the |
| | | | | | surface; there was a |
| | | | | | similar chemistry |
| | | | | | composition |
| | | | | | between the |
| | | | | | discolored area and |
| | | | | | the surrounding |
| | | | | | normal area |
| ENP | 16.4917 | 16.4921 | 0.00 | 36.1 | Pebble patterns |
| | | | | | detected; NiF₂ |
| | | | | | formed on surface; |
| | | | | | phosphorus level |
| | | | | | reduced |
| NiF₂ | 22.9073 | 22.9073 | 0.00 | 61.5 | No observable |
| | | | | | change; the fluorine |
| | | | | | level increased |
| | | | | | slightly due to |
| | | | | | conversion of |
| | | | | | surface oxide to |
| | | | | | fluoride |
| PS YF₃ | 9.5636 | 9.5654 | -0.02 | N/A | Cracked |
| Dura YF₃ | 10.9419 | 10.9422 | 0.00 | N/A | Cracked |

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A chamber component for a processing chamber, comprising:
a substrate; and
a metal fluoride coating on the substrate, the metal fluoride coating comprising at least one of:
a formula M1ₓF_{w}, wherein x has a value of 1 and w has a value from 1 to 3;
a formula M1ₓM2_{y}F_{w}, wherein x has a value from 0.1 to 1, y has a value from 0.1 to 1, and w has a value from 1 to 3; or
a formula M1ₓM2_{y}M3_{z}F_{w}, wherein x has a value from 0.1 to 1, y has a value from 0.1 to 1, z has a value from 0.1 to 1 and w has a value from 1 to 3, and
wherein at least one of M1, M2, or M3 comprises nickel.

2. The chamber component of claim 1, wherein M2 and M3 is each independently a metal selected from the group consisting of magnesium, aluminum, cobalt, chromium and yttrium.

3. The chamber component of claim 1, wherein the metal fluoride coating comprises an electroless metal plated coating layer comprising nickel or an electrolytic metal plated coating layer comprising nickel.

4. The chamber component of claim 3, wherein the electroless metal plated coating layer comprises a nano-crystalline structure comprising tetragonal nickel phosphide (Ni₃P) and cubic Ni.

5. The chamber component of claim 3, wherein the electroless metal plated coating layer or the electrolytic metal plated coating layer comprises phosphorus (P), and wherein the metal fluoride coating is free of phosphorus.

6. The chamber component of claim 1, wherein the metal fluoride coating is crystalline.

7. The chamber component of claim 6, wherein the metal fluoride coating comprises a tetragonal P4₂/mnm crystalline structure.

8. The chamber component of claim 1, wherein the substrate comprises aluminum alloy, aluminum nitride (AlN), alumina (Al₂O₃), nickel (Ni), stainless steel, nickel-chromium alloy, austenitic nickel-chromium-based superalloy, pure nickel, quartz, iron, cobalt, titanium, magnesium, copper, zinc, chromium or combinations thereof.

9. The chamber component of claim 1, wherein the chamber component is a semiconductor chamber component and wherein the substrate is a heater, an electrostatic chuck, a faceplate, a showerhead, a liner, a blocker plate, a gas box, an edge ring, or a bellows.

10. A method for reducing particles during processing in a processing chamber, comprising:
contacting a substrate with fluorine to form a metal fluoride coating,
wherein the metal fluoride coating comprises at least one of:
a formula M1ₓF_{w}, wherein x has a value of 1 and w has a value from 1 to 3;
a formula M1ₓM2_{y}F_{w}, wherein x has a value from 0.1 to 1, y has a value from 0.1 to 1, and w has a value from 1 to 3; or
a formula M1ₓM2_{y}M3_{z}F_{w}, wherein x has a value from 0.1 to 1, y has a value from 0.1 to 1, z has a value from 0.1 to 1 and w has a value from 1 to 3, and
wherein at least one of M1, M2, or M3 comprises nickel.

11. The method of claim 10, wherein M2 and M3 is each independently a metal selected from the group consisting of magnesium, aluminum, cobalt, chromium and yttrium.

12. The method of claim 10, further comprising depositing an electroless metal plated coating layer comprising nickel or an electrolytic metal plated coating layer comprising nickel on the substrate, wherein the contacting comprises contacting the electroless metal plated coating layer or the electrolytic metal plated coating layer with the fluorine to form the metal fluoride coating.

13. The method of claim 12, wherein the electroless metal plated coating layer comprises a nano-crystalline structure comprising tetragonal nickel phosphide (Ni₃P) and cubic Ni.

14. The method of claim 12, wherein the electroless metal plated coating layer or the electrolytic metal plated coating layer further comprises phosphorus (P), and wherein the metal fluoride coating is free of phosphorus.

15. The method of claim 10, wherein the substrate comprises aluminum alloy, aluminum nitride (AlN), alumina (Al₂O₃), nickel (Ni), stainless steel, nickel-chromium alloy, austenitic nickel-chromium-based superalloy, pure nickel, quartz, iron, cobalt, titanium, magnesium, copper, zinc, chromium or combinations thereof.

16. The method of claim 10, wherein the substrate is a heater, an electrostatic chuck, a faceplate, a showerhead, a liner, a blocker plate, a gas box, an edge ring or a bellows.

17. A processing chamber, comprising:
a chamber component, comprising:
a substrate; and
a metal fluoride coating on a surface of the substrate, the metal fluoride coating comprising at least one of:
a formula M1ₓF_{w}, wherein x has a value of 1 and w has a value from 1 to 3;
a formula M1ₓM2_{y}F_{w}, wherein x has a value from 0.1 to 1, y has a value from 0.1 to 1, and w has a value from 1 to 3; or
a formula M1ₓM2_{y}M3_{z}F_{w}, wherein x has a value from 0.1 to 1, y has a value from 0.1 to 1, z has a value from 0.1 to 1 and w has a value from 1 to 3, and
wherein at least one of M1, M2, or M3 comprises nickel.

18. The processing chamber of claim 17, wherein M2 and M3 each independently is a metal selected from the group consisting of magnesium, aluminum, cobalt, chromium and yttrium.

19. The processing chamber of claim 17, wherein the metal fluoride coating comprises an electroless metal plated coating layer comprising nickel or an electrolytic metal plated coating layer comprising nickel.

20. The chamber component of claim 19, wherein the electroless metal plated coating layer comprises a nano-crystalline structure comprising tetragonal nickel phosphide (Ni₃P) and cubic Ni, and wherein the metal fluoride coating is free of phosphorus.
